(19) United States
(12) Patent Application Publication
(10) Pub. No.: US 2026/0305049 A1
(43) Pub. Date: Oct. 1, 2026

(54) ORGANIC THIN FILM TRANSISTOR AND MANUFACTURING METHOD THEREFOR, ARRAY SUBSTRATE, AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Liwen DONG, Beijing (CN); Dongfei HOU, Beijing (CN); Changhan HSIEH, Beijing (CN); Feng ZHANG, Beijing (CN); Zhao CUI, Beijing (CN); Wenqu LIU, Beijing (CN); Zhijun LV, Beijing (CN); Detian MENG, Beijing (CN); Qi YAO, Beijing (CN)

(73) Assignees: Beijing BOE Technology Development Co., Ltd., Beijing (CN); BOE TECHNOLOGY GROUP CO., LTD., Beijing (CN)

(21) Appl. No.: 19/479,384

(22) PCT Filed: Apr. 22, 2024
(86) PCT No.: PCT/CN2024/089176

§ 371 Date: Oct. 28, 2025

(30) Foreign Application Priority Data
May 30, 2023 (CN) 202310632085.4

(51) Int. Cl. H10K 10/82; G02F 1/1335; G02F 1/1368; H10K 10/46; H10K 19/10; H10K 71/60

(52) U.S. Cl. CPC H10K 10/82; G02F 1/1368; H10K 10/484; H10K 71/60; G02F 1/133514; H10K 19/10

(57) ABSTRACT

An organic thin film transistor includes a first electrode and a second electrode that are spaced apart, an active layer, and an auxiliary electrode located on the first electrode and in contact with the first electrode. The active layer includes a first overlap portion, an active portion and a second overlap portion which are sequentially connected. The first overlap portion is overlapped on the first electrode, and the second overlap portion is overlapped on the second electrode. An orthographic projection of the auxiliary electrode is located within an orthographic projection of the first electrode. There is a distance between the auxiliary electrode and the first overlap portion. A material of the active layer is an organic semiconductor material, and a ratio of a thickness of at least one of the first electrode and the second electrode to a thickness of the active layer ranges from 1:8 to 9:4.

### CROSS-REFERENCE TO RELATED APPLICATIONS

This application is a national phase entry under 35 USC 371 of International Patent Application No. PCT/CN 2024/089176, filed on Apr. 22, 2024, which claims priority to Chinese Patent Application No. 202310632085.4, filed on May 30, 2023, each are incorporated herein by reference in their entirety.

### TECHNICAL FIELD

The present disclosure relates to the field of display technologies, and in particular, to an organic thin film transistor and a method for manufacturing the same, an array substrate and a display device.

### BACKGROUND

Depending on different semiconductor materials of active layers of thin film transistors (TFTs), traditional thin film transistors mainly include amorphous silicon thin film transistors, polycrystalline silicon thin film transistors and oxide thin film transistors.

### SUMMARY

In an aspect, an organic thin film transistor is provided and includes a substrate, a first electrode, a second electrode, an active layer and an auxiliary electrode. The first electrode and the second electrode are located on the substrate. The first electrode and the second electrode are spaced apart. The active layer includes a first overlap portion, an active portion and a second overlap portion that are connected in sequence. The first overlap portion is overlapped on the first electrode, the second overlap portion is overlapped on the second electrode, and the active portion is located between the first electrode and the second electrode. The auxiliary electrode is located on the first electrode and in contact with the first electrode. An orthographic projection of the auxiliary electrode on the substrate is located within an orthographic projection of the first electrode on the substrate. The auxiliary electrode and the first overlap portion have a distance therebetween. A material of the active layer is an organic semiconductor material, and a ratio of a thickness of at least one of the first electrode and the second electrode to a thickness of the active layer is in a range of 1:8 to 9:4, inclusive.

In some embodiments, a thickness of the auxiliary electrode is greater than a thickness of the first electrode.

In some embodiments, a ratio of a thickness of the auxiliary electrode to the thickness of the active layer is in a range of 5:1 to 15:1, inclusive.

In some embodiments, the organic thin film transistor further includes a gate insulating layer, an auxiliary layer and a gate. The gate insulating layer is located on the active layer, and a material of the gate insulating layer includes an organic material. The auxiliary layer is located on the gate insulating layer, and orthographic projections of the auxiliary layer, the gate insulating layer and the active layer on the substrate coincide. The gate is located on the auxiliary layer and in contact with the auxiliary layer.

In some embodiments, a material of the auxiliary layer includes a conductive material or an organic material.

In some embodiments, the organic thin film transistor further includes a passivation layer. The passivation layer is located on a side of the auxiliary layer away from the substrate. The passivation layer includes a first via hole, and a material of the passivation layer includes an organic material. The gate is located on the passivation layer. The gate includes a first sub-gate and a second sub-gate that are stacked; and the first sub-gate is in contact with the auxiliary layer through the first via hole.

In some embodiments, the organic thin film transistor further includes a gate and a protective layer. The gate is located on a side of the active layer proximate to the substrate. The protective layer is located on a surface of the active layer away from the substrate. An orthographic projection of the protective layer on the substrate coincides with an orthographic projection of the active layer on the substrate, and a material of the protective layer includes an organic material.

In some embodiments, the organic thin film transistor further includes a gate insulating layer. The gate insulating layer is located between the active layer and the gate; and a material of the gate insulating layer includes an organic material.

In some embodiments, the material of the active layer includes polythiophene-based semiconductor materials and pentacene-based small molecule semiconductor materials.

In some embodiments, the thickness of the at least one of the first electrode and the second electrode is in a range of 10 nm to 90 nm, inclusive.

In some embodiments, the thickness of the active layer is in a range of 40 nm to 80 nm, inclusive.

In some embodiments, the substrate includes a flexible substrate.

In another aspect, a method for manufacturing an organic thin film transistor is provided and includes: providing a substrate; forming a first electrode, an auxiliary electrode and a second electrode on the substrate, where the first electrode and the second electrode are spaced apart, the auxiliary electrode is located on the first electrode and in contact with the first electrode, and an orthographic projection of the auxiliary electrode on the substrate is located within an orthographic projection of the first electrode on the substrate; and forming an active layer, where the active layer includes a first overlap portion, an active portion and a second overlap portion that are connected in sequence, the first overlap portion is overlapped on the first electrode, the second overlap portion is overlapped on the second electrode, and the active portion is located between the first electrode and the second electrode, the auxiliary electrode and the first overlap portion have a distance therebetween, a material of the active layer is an organic semiconductor material, and a ratio of a thickness of at least one of the first electrode and the second electrode to a thickness of the active layer is in a range of 1:8 to 9:4, inclusive.

In some embodiments, forming the first electrode, the auxiliary electrode and the second electrode on the substrate includes: forming a first conductive film and a second conductive film sequentially on the substrate; forming a photoresist film on the second conductive film; performing exposure and development on the photoresist film using a halftone mask, where the halftone mask has a completely transparent area, a first semi-transparent area and an opaque area, a portion of the photoresist film located in the completely transparent area is removed, a portion of the photoresist film located in the first semi-transparent area is thinned to obtain a first photoresist pattern, and a portion of the photoresist film located in the opaque area is retained to obtain a second photoresist pattern; with the first photoresist pattern and the second photoresist pattern as a mask, etching the first conductive film and the second conductive film to remove the first photoresist pattern and thin the second photoresist pattern simultaneously to obtain a first conductive pattern and a second conductive pattern; and with the thinned second photoresist pattern as a mask, etching portions of the first conductive pattern and the second conductive pattern located in the second conductive film, to retain portions of the first conductive pattern and the second conductive pattern located in the first conductive film to obtain the first electrode and the second electrode, and to retain a portion of the first conductive pattern and the second conductive pattern located in the second conductive film and covered by the thinned second photoresist pattern to obtain the auxiliary electrode.

In some embodiments, forming the active layer includes: forming an active film, a gate insulating film and an auxiliary film sequentially on the substrate, the first electrode, the auxiliary electrode and the second electrode; performing patterning on the auxiliary film to form an auxiliary layer; and performing patterning on the gate insulating film and the active film with the auxiliary layer as a mask to form a gate insulating layer and the active layer.

In some embodiments, after forming the gate insulating layer and the active layer, the method further includes: forming a passivation layer on the auxiliary layer, where the passivation layer includes a first via hole; forming a gate film on the passivation layer; and performing patterning on the gate film to form a gate, wherein the gate is in contact with the auxiliary layer.

In yet another aspect, an array substrate is provided and includes: a plurality of organic thin film transistors each as described in any of the above embodiments; and a plurality of pixel electrodes electrically connected to second electrodes of the plurality of organic thin film transistors, respectively.

In some embodiments, the array substrate further includes data lines. The plurality of organic thin film transistors are arranged in an array. First electrodes of organic thin film transistors located in a same column are electrically connected to each other, and auxiliary electrodes of the organic thin film transistors located in the same column are electrically connected to each other, so as to form a data line.

In some embodiments, each pixel electrode is located between a second electrode of a corresponding organic thin film transistor and the substrate, and a portion of the second electrode of the organic thin film transistor is overlapped on the pixel electrode.

In some embodiments, the array substrate further includes a common electrode and gate lines. The organic thin film transistors each further include a passivation layer and a gate located on a side of the passivation layer away from the substrate, and the gate includes a first sub-gate and a second sub-gate that are stacked. The common electrode is located on a side of the passivation layer in the organic thin film transistor away from the substrate. The plurality of organic thin film transistors are arranged in an array. First sub-gates of gates of organic thin film transistors located in a same row are electrically connected to each other to form a first sub-line, second sub-gates of the gates of the organic thin film transistors located in the same row are electrically connected to each other to form a second sub-line, and the first sub-line and the second sub-line constitute a gate line. The first sub-line is disposed in a same layer as the common electrode.

In some embodiments, the array substrate further includes gate lines. The organic thin film transistors each further include a passivation layer and a gate located on a side of the passivation layer away from the substrate; and the gate includes a first sub-gate and a second sub-gate that are stacked. The plurality of organic thin film transistors are arranged in an array; first sub-gates of gates of organic thin film transistors located in a same row are electrically connected to each other to form a first sub-line, second sub-gates of the gates of the organic thin film transistors located in the same row are electrically connected to each other to form a second sub-line; and the first sub-line and the second sub-line constitute a gate line. The pixel electrodes are located on a side of the passivation layer away from the substrate. The first sub-line is disposed in a same layer as the pixel electrodes.

In yet another aspect, a display device is provided and includes the array substrate as described in any of the above embodiments, a color film substrate located on a side of the array substrate, and a liquid crystal layer located between the array substrate and the color film substrate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product and an actual process of a method to which the embodiments of the present disclosure relate.

FIG. 1 is a schematic diagram of a display device, in accordance with some embodiments of the present disclosure;

FIG. 2 is a schematic diagram of another display device, in accordance with some embodiments of the present disclosure;

FIG. 3 is a structural diagram of an organic thin film transistor, in accordance with some embodiments of the present disclosure;

FIG. 4 is a partial structural diagram of an organic thin film transistor, in accordance with an implementation;

FIG. 5 is a structural diagram of another organic thin film transistor, in accordance with some embodiments of the present disclosure;

FIG. 6 is a structural diagram of another organic thin film transistor, in accordance with some embodiments of the present disclosure;

FIG. 7 is a partial structural diagram of another organic thin film transistor, in accordance with some embodiments of the present disclosure;

FIG. 8 is a scanning electron microscope diagram showing a structure of an organic thin film transistor, in accordance with an implementation;

FIG. 9 is a scanning electron microscope diagram showing a structure of an organic thin film transistor, in accordance with some embodiments of the present disclosure;

FIG. 10 is a structural diagram of another organic thin film transistor, in accordance with some embodiments of the present disclosure;

FIG. 11 is a structural diagram of an array substrate, in accordance with some embodiments of the present disclosure;

FIG. 12 is a structural diagram of another array substrate, in accordance with some embodiments of the present disclosure;

FIG. 13 is an equivalent circuit diagram of an array substrate, in accordance with some embodiments of the present disclosure;

FIG. 14 is a structural diagram of another array substrate, in accordance with some embodiments of the present disclosure;

FIG. 15 is a structural diagram of another array substrate, in accordance with some embodiments of the present disclosure;

FIG. 16 is a manufacturing flowchart of an organic thin film transistor, in accordance with some embodiments of the present disclosure;

FIGS. 17 and 19 to 29 are structural diagrams of an organic thin film transistor in different stages of a manufacturing process, in accordance with some embodiments of the present disclosure;

FIGS. 17 to 18 and 29 to 31 are structural diagrams of an array substrate in different stages of a manufacturing process, in accordance with some embodiments of the present disclosure;

FIG. 32 is a structural diagram of a display device in different stages of a manufacturing process, in accordance with some embodiments of the present disclosure; and

FIG. 33 is a structural diagram of another display device, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

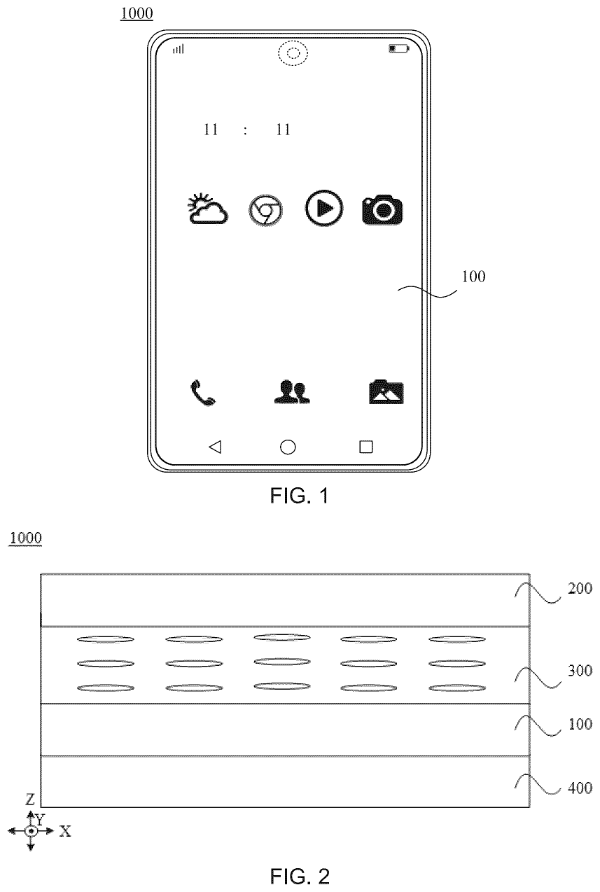

As shown in FIG. 1, some embodiments of the present disclosure provide a display device 1000. The display device 1000 may be any display device that displays images whether in motion (such as a video) or fixed (such as a still image), and regardless of text or image. More specifically, it is expected that the display device in the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

For example, the display device 1000 may be an organic light-emitting diode (OLED) display device or a liquid crystal display (LCD) display device.

For the LCD display device, as shown in FIG. 2, the display device 1000 includes an array substrate 100, a color film substrate 200 and a liquid crystal layer 300. The color film substrate 200 is located on a side of the array substrate 100. The liquid crystal layer 300 is located between the color film substrate 200 and the array substrate 100.

For example, as shown in FIG. 2, the display device 1000 further includes a backlight module 400. The backlight module 400 is located on a side of the array substrate 100 away from the liquid crystal layer 300. The backlight module 400 may be used as a backlight light source.

For example, backlight provided by the backlight module 400 may be white light or blue light.

The array substrate 100 includes a plurality of thin film transistors and a plurality of pixel electrodes. A pixel electrode is electrically connected to a thin film transistor and is used to receive a pixel voltage signal transmitted by the thin film transistor.

Generally speaking, the thin film transistor includes an active layer, and a material of the active layer is generally an inorganic material such as polycrystalline silicon.

In the related art, flexible display products are highly favored by consumers. For display devices, products commonly used for flexible display are OLED display devices. For the LCD display device, due to structural characteristics of thin film transistors in the array substrate, when the LCD display device is bent or curved, active layers of the thin film transistors are prone to cracks or fractures, resulting in affecting the normal operation of the thin film transistors, thereby making it difficult for the display device to achieve flexible display.

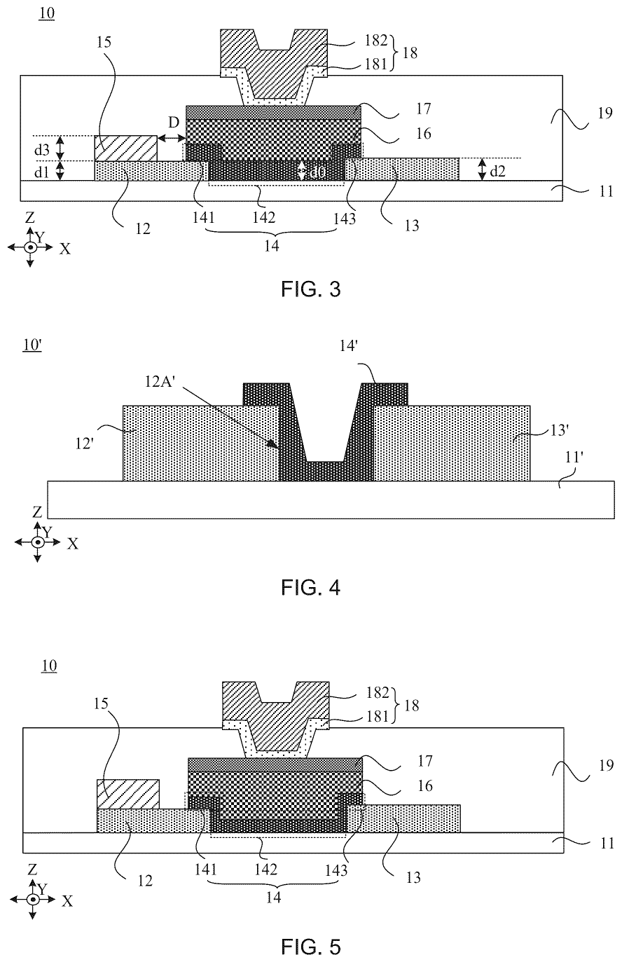

In light of this, as shown in FIG. 3, some embodiments of the present disclosure provide an organic thin film transistor 10. The organic thin film transistor 10 may be used in the array substrate and the display device described above, so that the display device may achieve flexible display.

The organic thin film transistor 10 includes a substrate 11, a first electrode 12, a second electrode 13, an active layer 14 and an auxiliary electrode 15.

For example, the substrate 11 may be a flexible substrate or a rigid substrate. For example, in a case where the substrate 11 is a flexible substrate, the substrate 11 may be made of dimethylsiloxane, polyimide (PI), polyethylene terephthalate (PET) or other highly elastic materials. As another example, in a case where the substrate 11 is a rigid substrate, the substrate 11 may be made of glass or the like.

Of course, the substrate 11 may also be a composite substrate. For example, the material of the substrate 11 may include both glass and PI.

In some examples, the first electrode 12 and the second electrode 13 are located on the substrate 11. The first electrode 12 is spaced apart from the second electrode 13.

For example, the substrate 11 has a flat-plate structure, and the first electrode 12 and the second electrode 13 are located on the same surface of the substrate 11. The first electrode 12 and the second electrode 13 are not in contact with each other and have a certain distance therebetween.

For example, a thickness d1 of the first electrode 12 is substantially equal to a thickness d2 of the second electrode 13.

In the organic thin film transistors 10 provided by the embodiments of the present disclosure, a first electrode 12 of the organic thin film transistor 10 is one of a source and a drain, and a second electrode 13 of the organic thin film transistor 10 is the other one of the source and the drain. Since the source and the drain of the organic thin film transistor 10 may be symmetrical in structure, there may be no difference in structure between the source and the drain of the organic thin film transistor. That is, there may be no difference in structure between the first electrode 12 and the second electrode 13 of the organic thin film transistor 10 in the embodiments of the present disclosure. For example, for the P-type organic thin film transistor 10, the first electrode 12 of the organic thin film transistor 10 is referred to as the source, and the second electrode 13 of the organic thin film transistor 10 is referred to as the drain. For example, for the N-type organic thin film transistor 10, the first electrode 12 of the organic thin film transistor 10 is referred to as the drain, and the second electrode 13 of the organic thin film transistor 10 is referred to as the source.

In some examples, the active layer 14 includes a first overlap portion 141, an active portion 142 and a second overlap portion 143 that are sequentially connected. The first overlap portion 141 is overlapped on the first electrode 12, the second overlap portion 143 is overlapped on the second electrode 13, and the active portion 142 is located between the first electrode 12 and the second electrode 13.

For example, there is no hollow space between the first overlap portion 141, the active portion 142 and the second overlap portion 143 that are sequentially connected.

The first overlap portion 141 is located on a surface of the first electrode 12 away from the substrate 11, and the first overlap portion 141 covers a portion of the first electrode 12. An orthographic projection of the first overlap portion 141 on the substrate 11 may be partially overlapped with an orthographic projection of the first electrode 12 on the substrate 11.

Thus, the first overlap portion 141 may be used to achieve electrical connection between the active layer 14 and the first electrode 12.

For example, the second overlap portion 143 is located on a surface of the second electrode 13 away from the substrate 11, and the second overlap portion 143 covers a portion of the second electrode 13.

For example, an orthographic projection of the second overlap portion 143 on the substrate 11 may be partially overlapped with an orthographic projection of the second electrode 13 on the substrate 11.

Thus, the second overlap portion 143 may be used to achieve electrical connection between the active layer 14 and the second electrode 13.

The first electrode 12 has a sidewall, and the active portion 142 is in contact with part of the sidewall of the first electrode 12. The second electrode 13 has a sidewall, and the active portion 142 is in contact with part of the sidewall of the second electrode 13.

For example, the active portion 142 located between the first electrode 12 and the second electrode 13 is located on a side of the substrate 11, and is located on the same side of the substrate 11 as the first electrode 12 or the second electrode 13. The first overlap portion 141, the active portion 142 and the second overlap portion 143 have substantially the same thicknesses.

In some examples, a material of the active layer 14 includes an organic semiconductor material.

The organic semiconductor material has certain flexibility and is not prone to cracks or fractures when being bent or folded under action of external force. Therefore, in a case where the organic thin film transistor 10 made of the active layer 14 and the array substrate 100 are applied to the display device 1000, the display device 1000 may achieve flexible display, which may avoid affecting transmission of the pixel voltage signal and thus affecting a display effect due to cracks in the active layer 14 during bending or folding.

In some examples, the auxiliary electrode 15 is located on the first electrode 12 and in contact with the first electrode 12. An orthographic projection of the auxiliary electrode 15 on the substrate 11 is located within an orthographic projection of the first electrode 12 on the substrate 11. There is a distance D between the auxiliary electrode 15 and the first overlap portion 141.

For example, the auxiliary electrode 15 is electrically connected to the first electrode 12. The auxiliary electrode 15 covers a portion of the first electrode 12. Moreover, a portion of the first electrode 12 covered by the auxiliary electrode 15 and a portion of the first electrode 12 covered by the first overlap portion 141 do not overlap. For example, a boundary line of the orthographic projection of the auxiliary electrode 15 on the substrate 11 is located within a boundary line of the orthographic projection of the first electrode 12 on the substrate 11, and there is a distance between the two.

With the above provision, the auxiliary electrode 15 is located on the first electrode 12, so that the auxiliary electrode 15 may be used to reduce an overall resistance of the first electrode 12 and the auxiliary electrode 15. As a result, a signal has a small loss on the first electrode 12 and the auxiliary electrode 15, which is beneficial to ensuring an accuracy of the signal transmitted by the organic thin film transistor 10, thereby ensuring a good display effect of the display device 1000.

In an implementation, as shown in FIG. 4, in order to reduce a resistance of a film layer where a first electrode 12′ and a second electrode 13′ of an organic thin film transistor 10′ are located, the first electrode 12′ and the second electrode 13′ are set to have large thicknesses. For example, the thickness of the first electrode 12′ is in a range of 400 nm to 600 nm, inclusive. However, after the relatively thick first electrode 12′ is formed, in a process of a material of the active layer 14′ climbing along a sidewall 12A′ of the first electrode 12′ to a surface of the first electrode 12′ away from the substrate 11′, due to a relatively large step difference between the first electrode 12′ and the substrate 11′, cracks or even fractures (cracks or fractures are not shown in FIG. 4) are likely to occur in a portion of the active layer 14′ in contact with the sidewall 12A′ of the first electrode 12′. As a result, transport of carriers in the active layer 14′ is affected, thereby affecting electrical properties of the organic thin film transistor, such as an on-state current, carrier mobility and a threshold voltage of the organic thin film transistor. Similarly, the thickness of the second electrode 13′ is also relatively large, resulting in a relatively large step difference between the second electrode 13′ and the substrate 11′, and thus cracks or even fractures are likely to occur in a portion of the active layer 14′ in contact with a sidewall of the second electrode 13′, thereby affecting the electrical properties of the organic thin film transistor.

In light of this, in some embodiments of the present disclosure, a ratio of a thickness of at least one of the first electrode 12 and the second electrode 13 of the organic thin film transistor 10 to a thickness do of the active layer 14 is set in a range of 1:8 to 9:4, inclusive.

For example, a ratio of a thickness of the first electrode 12 to the thickness of the active layer 14 is in a range of 1:8 to 9:4, inclusive. Alternatively, a ratio of a thickness of the first electrode 12 to the thickness of the active layer 14 and a ratio of a thickness of the second electrode 13 to the thickness of the active layer 14 are each in a range of 1:8 to 9:4, inclusive.

For example, the ratio of the thickness of the at least one of the first electrode 12 and the second electrode 13 to the thickness of the active layer 14 is 1:8, 1:3, 1:1, 1:2 or 9:4.

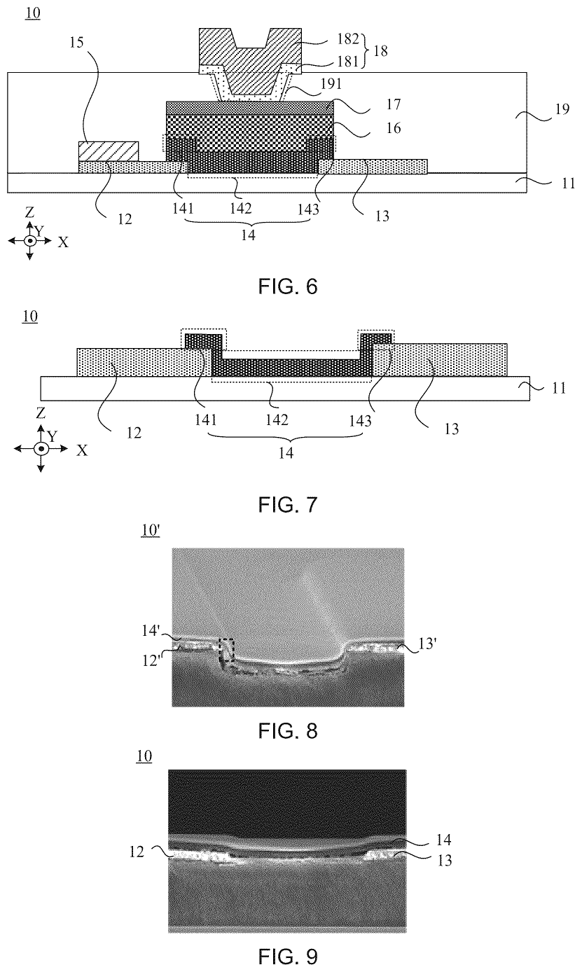

For example, as shown in FIG. 3, the thickness of the first electrode 12 is substantially equal to the thickness of the active layer 14. As shown in FIG. 5, the thickness of the first electrode 12 is slightly greater than the thickness of the active layer 14. As shown in FIG. 6, the thickness of the first electrode 12 is less than the thickness of the active layer 14.

With the above provision, the material of the active layer may climb a relatively low height, thereby alleviating or even eliminating occurrence of cracks and fractures between the first overlap portion 141 of the active layer 14 and the active portion 142 or between the second overlap portion 143 of the active layer 14 and the active portion 142. Thus, normal transport of the carriers in the active layer 14 may be ensured, so as to guarantee electrical properties of the organic thin film transistor 10 and guarantee the accuracy of the signal transmitted by the organic thin film transistor 10, thereby ensuring a good display effect of the display device 1000.

The organic thin film transistor 10 provided in some embodiments of the present disclosure includes the substrate 11, the first electrode 12, the second electrode 13 and the active layer 14. The material of the active layer 14 is an organic semiconductor material, so that the organic thin film transistor 10 has certain flexibility. In a case where the organic thin film transistor 10 is bent or curved when subjected to external force, the damage to the active layer 14 may be alleviated, thereby ensuring the electrical properties of the organic thin film transistor 10. Therefore, the organic thin film transistor 10 may be applied to the flexible display device. Moreover, the first overlap portion 141 of the active layer 14 is overlapped on the first electrode 12, the second overlap portion 143 of the active layer 14 is overlapped on the second electrode 13, and the active portion 142 of the active layer 14 is located between the first overlap portion 141 and the second overlap portion 143. The ratio of the thickness of the at least one of the first electrode 12 and the second electrode 13 to the thickness of the active layer 14 is in a range of 1:8 to 9:4, inclusive. Thus, the first electrode 12 and the substrate 11 or the second electrode 13 and the substrate 11 may have a small step difference therebetween, so that the material of the active layer may climb a relatively low height, thereby alleviating or even eliminating occurrence of cracks and fractures between the first overlap portion 141 of the active layer 14 and the active portion 142 or between the second overlap portion 143 of the active layer 14 and the active portion 142. Thus, normal transport of the carriers in the active layer 14 may be ensured, so as to guarantee electrical properties of the organic thin film transistor 10 and guarantee the accuracy of the signal transmitted by the organic thin film transistor 10, thereby ensuring a good display effect of the display device 1000.

In addition, the organic thin film transistor 10 further includes the auxiliary electrode 15 in contact with the first electrode 12. The auxiliary electrode 15 covers a portion of the first electrode 12, and there is a distance between the auxiliary electrode 15 and the first overlap portion 141. Thus, the auxiliary electrode 15 may be used to reduce an overall resistance of the first electrode 12 and the auxiliary electrode 15, so that a signal (e.g., data signal) has a small loss on the first electrode 12 and the auxiliary electrode 15, which is beneficial to ensuring an accuracy of the signal transmitted by the organic thin film transistor 10, thereby further ensuring a good display effect of the display device 1000.

In some examples, a thickness of at least one of the first electrode 12 and the second electrode 13 is in a range of 10 nm to 90 nm, inclusive.

For example, the thickness of the at least one of the first electrode 12 and the second electrode 13 may be in a range of 10 nm to 30 nm, inclusive, a range of 20 nm to 70 nm, inclusive, a range of 30 nm to 90 nm, inclusive, a range of 50 nm to 80 nm, inclusive, or a range of 70 nm to 90 nm, inclusive.

For example, the thickness of the first electrode 12 and the thickness of the second electrode 13 may be equal or unequal.

For example, the thickness of the first electrode 12 is 10 nm, 35 nm, 40 nm, 70 nm or 90 nm.

For example, the thickness of the second electrode 13 is 10 nm, 39 nm, 57 nm, 78 nm or 90 nm.

With the above provision, the at least one of the first electrode 12 and the second electrode 13 may have a small thickness, so that the at least one of the first electrode 12 and the second electrode 13 and the substrate 11 may have a small step difference therebetween, and thus the active layer 14 may climb gently. As a result, it may reduce or even avoid a possibility of cracks or fractures of the active layer 14 appearing on the sidewalls of the first electrode 12 or the second electrode 13, so as to ensure a complete and unbroken structure of the active layer 14, thereby ensuring the normal transport of carriers in the active layer 14 and guaranteeing the accuracy of the signal transmitted by the organic thin film transistor 10. Thus, the display device 1000 may have a good display effect.

The inventors of the present disclosure conducted experiments on the organic thin film transistor 10 formed using the above provision to observe whether the active layer 14 was broken. In the experiments, the thickness of the first electrode 12 was set equal to the thickness of the second electrode 13, and the thickness of the first electrode 12′ was set to 400 nm (as shown in FIG. 4) and the thickness of the first electrode 12 was set to 90 nm (as shown in FIG. 7), respectively. The scanning electron microscope (SEM) was used to observe the morphology of the formed active layer.

FIG. 8 is a partial SEM image of the active layer 14′ and the first electrode 12′ in a case where the thickness of the first electrode 12′ is 400 nm. It can be seen that an overlapping position (a position framed by the dotted box in FIG. 8) of the active layer 14′ and the first electrode 12′ is broken. FIG. 9 is a partial SEM image of the active layer 14 and the first electrode 12 in a case where the thickness of the first electrode 12 is 90 nm. It can be seen that there is no break at an overlapping position between the active layer 14 and the first electrode 12. Therefore, the first electrode 12 formed within the above thickness range set in the present disclosure may ensure that the active layer 14 of the organic thin film transistor 10 is not broken, thereby ensuring the normal operation of the organic thin film transistor 10.

In some examples, a thickness of the active layer 14 is in a range of 40 nm to 80 nm, inclusive.

For example, the thickness of the active layer 14 may be in a range of 40 nm to 70 nm, inclusive, a range of 46 nm to 72 nm, inclusive, a range of 50 nm to 80 nm, inclusive, a range of 55 nm to 80 nm, inclusive, or a range of 70 nm to 80 nm, inclusive.

For example, the thickness of the active layer 14 is 40 nm, 55 nm, 63 nm, 75 nm or 80 nm.

Setting the thickness of the active layer 14 within the above range may reduce the thickness of the active layer 14, so that the thickness of the active layer 14 may match the thickness of the first electrode 12 and the thickness of the second electrode 13, so as to avoid fracture of the active layer 14, which is conducive to formation of the carrier transport channels, improvement of the carrier mobility, and improvement of the electrical properties of the organic thin film transistor 10. Thus, the accuracy of signal transported by the organic thin film transistor 10 may be ensured, thereby being beneficial to improving the display effect of the display device 1000.

In some examples, the material of the active layer 14 includes polythiophene-based semiconductor materials and pentacene-based small molecule semiconductor materials.

As a result, the materials of the first electrode 12 and the second electrode 13 may have a wide selection range, so that valence bands of the first electrode 12 and the second electrode 13 may match both a HOMO (highest occupied molecular orbital) energy level and a LUMO (lowest unoccupied molecular orbital) energy level of the active layer 14, thereby ensuring high carrier mobility of the organic thin film transistor 10 and improving the electrical properties of the organic thin film transistor 10.

In some examples, as shown in FIG. 6, a thickness d3 of the auxiliary electrode 15 is greater than a thickness of the first electrode 12. Thus, the overall resistance of the auxiliary electrode 15 and the first electrode 12 may be small, so that the signal transmitted by the auxiliary electrode 15 may have a small loss, thereby ensuring the accuracy of the transmitted signal, and further ensuring the accuracy of the signal transmitted by the organic thin film transistor 10.

In some examples, as shown in FIG. 5, a ratio of the thickness of the auxiliary electrode 15 to the thickness of the active layer 14 is in a range of 5:1 to 15:1, inclusive.

For example, the ratio of the thickness of the auxiliary electrode 15 to the thickness of the active layer 14 may be in a range of 5:1 to 10:1, inclusive, a range of 8:1 to 15:1, inclusive, a range of 10:1 to 15:1, inclusive, a range of 7:1 to 10:1, inclusive, or a range of 9:1 to 12:1, inclusive.

For example, the ratio of the thickness of the auxiliary electrode 15 to the thickness of the active layer 14 is 5:1, 7:1, 9:1, 11:1 or 15:1.

With the above provision, the thickness of the auxiliary electrode 15 may be made relatively large, so as to make the overall resistance of the auxiliary electrode 15 and the first electrode 12 small, thereby ensuring the accuracy of the signal transmitted by the organic thin film transistor 10.

The thickness of the auxiliary electrode 15 is in a range of 400 nm to 600 nm, inclusive. For example, the thickness of the auxiliary electrode 15 is 400 nm, 460 nm, 500 nm, 570 nm or 600 nm.

It can be understood that the organic thin film transistor 10 may have a top-gate bottom-contact structure or a bottom-gate bottom-contact structure, and selection may be made depending on actual needs, which is not limited in the embodiments of the present disclosure.

In some embodiments, as shown in FIG. 6, the organic thin film transistor 10 may have a top-gate bottom-contact structure. The organic thin film transistor 10 further includes a gate insulating layer 16, an auxiliary layer 17 and a gate 18.

In some examples, the gate insulating layer 16 is located on the active layer 21. The gate insulating layer 16 is used to isolate the active layer 14 from the gate 18.

For example, the material of the gate insulating layer 16 includes an organic material. Therefore, when the organic thin film transistor 10 is bent or curved, the gate insulating layer 16 is not prone to cracks or fractures, and thus an isolation effect of the gate insulating layer 16 on the active layer 14 and the gate electrode 18 may not be affected. Furthermore, in a case where the organic thin film transistor 10 is applied to the display device 1000, it is beneficial to realize flexible display of the display device 1000.

In some examples, the auxiliary layer 17 is located on the gate insulating layer 16, and orthographic projections of the auxiliary layer 17, the gate insulating layer 16 and the active layer 14 on the substrate 11 coincide.

For example, boundary lines of the orthographic projections of the auxiliary layer 17, the gate insulating layer 16 and the active layer 14 on the substrate 11 coincide.

The auxiliary layer 17 and the gate insulating layer 16 may protect the active layer 14, so as to ensure the stability of the active layer 14 and the high carrier mobility, thereby preventing the active layer 14 from being damaged due to bombardment by atomic or ion (e.g., atoms or ions generated during formation of the gate 18 or other structures).

In some examples, the gate 18 is located on the auxiliary layer 17 and is in contact with the auxiliary layer 17.

Since the orthographic projections of the auxiliary layer 17 and the active layer 14 on the substrate 11 coincide with each other, and the gate 18 is located on the auxiliary layer 17, the orthographic projection of the gate 18 on the substrate 11 and the orthographic projection of the active layer 14 on the substrate 11 have overlap portions. Therefore, a scanning signal received by the gate 18 may be used to control on or off of the signal transmission from the first electrode 12 to the second electrode 13.

In some examples, the material of the auxiliary layer 17 includes a conductive material or an organic material.

In a case where the auxiliary layer 17 is made of a conductive material, the auxiliary layer 17 and the gate 18 are electrically connected to each other, and the auxiliary layer 17 becomes a part of the gate 18 for receiving a signal from the gate 18 and protecting the active layer 14.

In a case where the auxiliary layer 17 is made of an organic material, the auxiliary layer 17 may protect the active layer 14 and improve the stability of the active layer 14.

In some examples, as shown in FIG. 6, the organic thin film transistor 10 further includes a passivation layer 19.

The passivation layer 19 is located on a side of the auxiliary layer 17 away from the substrate 11. The passivation layer 19 includes a first via hole 191. The first via hole 191 exposes part of a surface of the auxiliary layer 17 away from the substrate.

For example, the passivation layer 19 covers the first electrode 12, the second electrode 13 and the auxiliary electrode 15, so as to prevent them from being damaged by the external environment.

A material of the passivation layer 19 includes an organic material. The organic material has certain flexibility, and thus the passivation layer 19 is not prone to cracks or fractures when being bent or curved when subjected to external force. As a result, the organic thin film transistor 10 has certain flexibility. In a case where the organic thin film transistor 10 is applied to the array substrate 100 and the display device 1000, it is beneficial for the display device 1000 to achieve flexible display.

For example, the gate 18 is located on the passivation layer 19. The gate 18 includes a first sub-gate 181 and a second sub-gate 182 that are stacked. The first sub-gate 181 is in contact with the auxiliary layer 17 through the first via hole 191.

For example, an orthographic projection of the first sub-gate 181 on the substrate 11 is substantially overlapped with an orthographic projection of the second sub-gate 182 on the substrate 11.

For example, in a case where the auxiliary layer 17 is made of a conductive material, the first sub-gate 181 is electrically connected to the auxiliary layer 17. Thus, a resistance of the gate 18 may be reduced, a loss of a signal from the gate 18 during transmission may be reduced, the accuracy of the signal from gate 18 may be improved, and the accuracy of the signal transmitted by the organic thin film transistor 10 may be improved, thereby ensuring the display effect of the display device 1000.

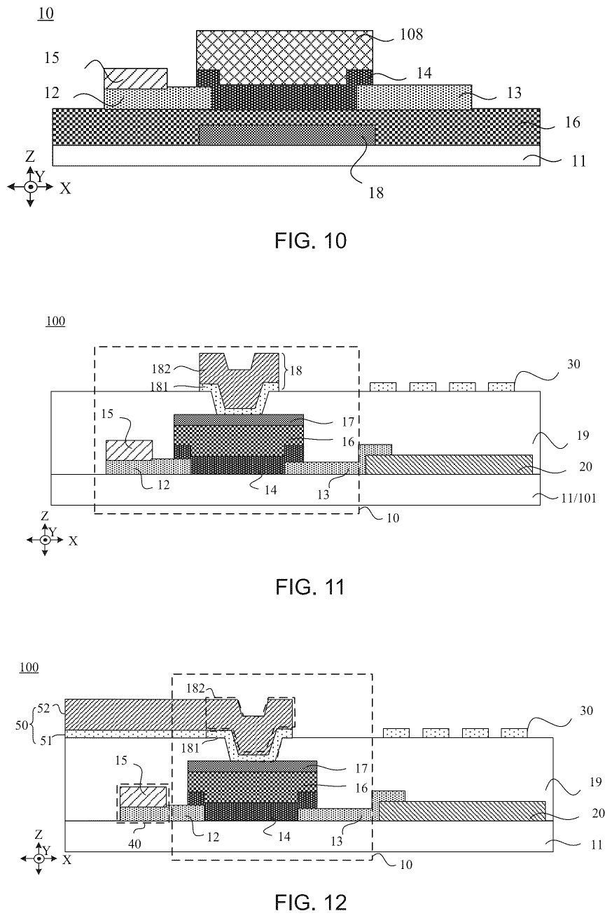

In some other embodiments, as shown in FIG. 10, the organic thin film transistor 10 may have a bottom-gate bottom-contact structure. The organic thin film transistor 10 further includes a gate 18 and a protective layer 108. The gate 18 is located on a side of the active layer 14 proximate to the substrate 11. The protective layer 108 is located on a surface of the active layer 14 away from the substrate 11. An orthographic projection of the protective layer 108 on the substrate 11 covers an orthographic projection of the active layer 14 on the substrate 11.

For example, the gate 18 is located between the active layer 14 and the substrate 11. The gate 18 may be in contact with the substrate 11.

For example, a boundary line of an orthographic projection of the protective layer 108 on the substrate 11 coincides with a boundary line of an orthographic projection of the active layer 14 on the substrate 11.

With the above provision, the protective layer 108 may be used to protect the active layer 14, so as to ensure the stability of the active layer 14 and the high carrier mobility, thereby preventing the active layer 14 from being damaged due to bombardment by atomic or ion (e.g., atoms or ions generated during formation of the pixel electrode or other structures).

In some examples, a material of the protective layer 108 includes an organic material.

For example, the material of the protective layer 108 is epoxy resin or PI.

With the above provision, the protective layer 108 may have certain flexibility. In a case where the organic thin film transistor 10 is applied to the flexible display device 1000, a risk of the protective layer 108 being broken may be reduced.

In some examples, as shown in FIG. 10, the organic thin film transistor 10 further includes a gate insulating layer 16. The gate insulating layer 16 is located between the active layer 14 and the gate 18.

The gate insulating layer 16 is used to isolate the active layer 14 from the gate 18. The first electrode 12 and the second electrode 13 are located on the gate insulating layer 16 on the substrate 11.

For example, a material of the gate insulating layer 16 may include an organic material. Thus, the gate insulating layer 16 may have certain flexibility, which facilitates application of the organic thin film transistor 10 in the display device 1000, so that the display device 1000 may achieve flexible display.

In the organic thin film transistor 10 provided in some embodiments of the present disclosure, the substrate 11 may be a flexible substrate, and the materials of the active layer 14, the gate insulating layer 16 and the passivation layer 19 may all be organic materials. Therefore, the organic thin film transistor 10 has certain flexibility. In a case where the organic thin film transistor 10 is bent or curved when subjected to external force, the substrate 11, the active layer 14, the gate insulating layer 16 and the passivation layer 19 are all not prone to cracks or fractures, and thus the normal operation of the organic thin film transistor 10 may not be affected. Therefore, in a case where the organic thin film transistor 10 is applied to the array substrate 100 and the display device 1000, the display device 1000 may achieve flexible display.

Furthermore, some embodiments of the present disclosure provide an array substrate 100. As shown in FIGS. 11 and 12, the array substrate 100 includes a plurality of organic thin film transistors 10 each as described in any of the above embodiments, and a plurality of pixel electrodes 20. The plurality of pixel electrodes 20 are electrically connected to the second electrodes 13 of the plurality of organic thin film transistors 10, respectively.

For example, the second electrode 13 of the organic thin film transistor 10 may provide a pixel voltage for the pixel electrode 20.

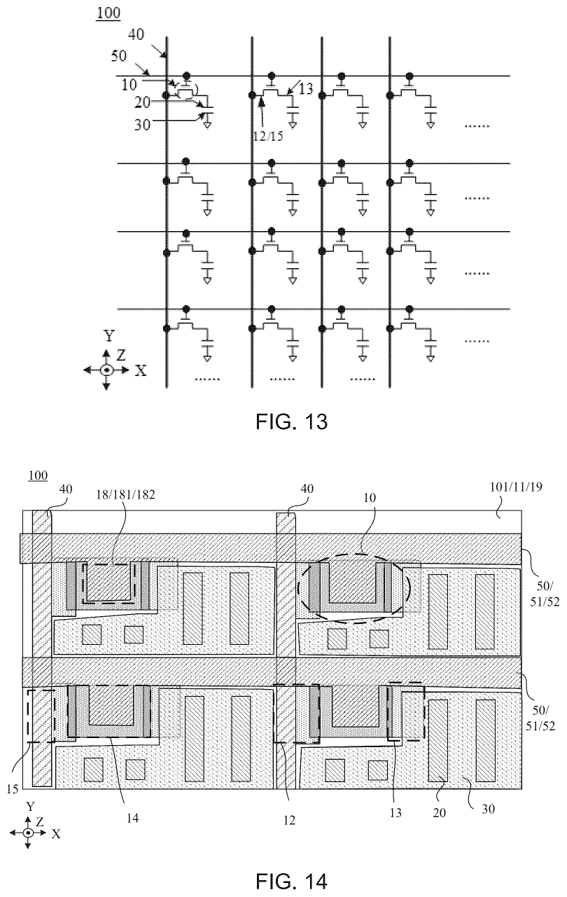

In some examples, as shown in FIG. 13, the plurality of organic thin film transistors 10 are arranged in an array. The organic thin film transistors 10 in each row are arranged in a first direction X. The organic thin film transistors 10 in each column are arranged in a second direction Y.

The first direction X and the second direction Y have an included angle therebetween. For example, an included angle between the first direction X and the second direction Y is 80°, 90°, 100°, 110°or 120°. The first direction X is parallel to a plane where the substrate 11 of the organic thin film transistor 10 is located, and the second direction Y is parallel to the plane where the substrate 11 of the organic thin film transistor 10 is located. The present disclosure will be described by considering an example where the included angle between the first direction X and the second direction Y is 90°.

The array substrate 100 further includes a first substrate 101, and the plurality of organic thin film transistor 10 and the plurality of pixel electrodes 20 are disposed on the first substrate 101.

For example, the array substrate 100 further includes a plurality of gate lines 50 and a plurality of data lines 40. For example, the plurality of gate lines 50 extend in the first direction X and are arranged at intervals in the second direction Y. The plurality of data lines 40 extend in the second direction Y and are arranged at intervals in the first direction X. A gate line 50 is electrically connected to gates 18 of organic thin film transistors 10 in a row and provides a scanning signal to the gates 18 of the organic thin film transistors 10 in the row. A data line 40 is electrically connected to first electrodes 12 of organic thin film transistors 10 in a column and provides a data signal (or a pixel voltage signal) to the first electrodes 12 of the organic thin film transistors 10 in the column.

In some examples, as shown in FIG. 14, first electrodes 12 of organic thin film transistors 10 located in the same column are electrically connected to each other, and auxiliary electrodes 15 of the organic thin film transistors 10 in the same column are electrically connected to each other, so as to form a data line 40.

In FIG. 14, Z is a direction perpendicular to the plane where the substrate 11 of the organic thin film transistor 10 is located. The direction Z is perpendicular to a plane defined by the first direction X and the second direction Y. In order to illustrate the relationship between the various film layers in the array substrate 100, the gate insulating layer 16 and the auxiliary layer 17 in the organic thin film transistor 10 are omitted in the top view of FIG. 14. In the top view of the array substrate 100, the gate insulating layer 16 and the auxiliary layer 17 have the same position as the active layer 14, and the orthographic projections of the gate insulating layer 16 and the auxiliary layer 17 on the first substrate 101 coincide with the orthographic projection of the active layer 14 on the first substrate 101.

It can be understood that the first electrodes 12 of the organic thin film transistors 10 located in the same column are electrically connected to each other, which means that the portions of the first electrodes 12 covered by the corresponding auxiliary electrodes 15 are electrically connected to each other.

The data line 40 may receive and transmit a data signal.

In some examples, as shown in FIGS. 12 and 14, first sub-gates 181 of gates 18 of organic thin film transistors 10 located in the same row are electrically connected to each other to form a first sub-line 51, and second sub-gates 182 of the gates 18 of the organic thin film transistors 10 located in the same row are electrically connected to each other to form a second sub-line 52. The first sub-line 51 and the second sub-line 52 constitute a gate line 50.

The gate line 50 is used to receive and transmit a scanning signal, and the organic thin film transistor 10 is turned on or off under control of the scanning signal at the gate 18 thereof. In a case where the organic thin film transistor 10 is turned on, a data signal transmitted by the data line 40 is transmitted from the first electrode 12 to the second electrode 13, and then transmitted to the pixel electrode 20.

It can be understood that a position of a common electrode may be selected depending on the type of the display device 1000, and is not limited in the present disclosure. For example, in a case where the display device 1000 has a VA (vertical alignment) type or a TN (twisted nematic) type, the common electrode 30 is provided in the color film substrate 200. In a case where the display device 1000 has an ADS (advanced super dimension switch) type, an IPS (in-plane switching) type or an FFS (fringe field switching) type, the common electrode 30 is provided in the array substrate 100.

The position of the pixel electrode 20 in the array substrate 100 may vary, and may be selected depending on actual needs, and is not limited in the present disclosure.

In some embodiments, as shown in FIG. 11, each pixel electrode 20 is located between a second electrode 13 of a corresponding organic thin film transistor 10 and the substrate 11, and a portion of the second electrode 13 of the organic thin film transistor 10 is overlapped on the pixel electrode 20.

Thus, the second electrode 13 of the organic thin film transistor 10 and the pixel electrode 20 may be electrically connected, so that the pixel electrode 20 receives a signal from the second electrode 13 of the organic thin film transistor 10.

For example, a material of the pixel electrode 20 may be a transparent conductive material, such as indium tin oxide (ITO).

For example, a thickness of the pixel electrode 20 may be in a range of 70 nm to 100 nm, inclusive. For example, the thickness of the pixel electrode 20 is 70 nm, 80 nm, 86 nm, 93 nm or 100 nm.

The plurality of pixel electrodes 20 may be arranged in an array.

For example, as shown in FIGS. 11 and 13, in a case where the display device 1000 has an ADS type, an IPS type or an FFS type, the array substrate 100 further includes a common electrode 30. The common electrode 30 is located on a side of the passivation layer 19 away from the substrate 11.

For example, the common electrode 30 is located on the passivation layer 19. The common electrode 30 is used to receive a common voltage.

It can be understood that the shape of the common electrode 30 in the top view may vary, and may be selected depending on actual needs, and is not limited in the present disclosure. FIG. 14 is a top view only showing a single shape of the common electrode 30. The common electrodes 30 corresponding to pixel electrodes 20 in the same row may be electrically connected to each other. The common electrodes 30 corresponding to pixel electrodes 20 in the same column may also be electrically connected to each other.

The common electrode 30 may receive a common voltage signal.

For example, a material of the common electrode 30 may be a transparent conductive material, such as ITO.

For example, the first sub-line is disposed in the same layer as the common electrode 30. Since the first sub-gates 181 in the same row are electrically connected to each other to form the first sub-line, the first sub-gates 181 are disposed in the same layer as the common electrode 30. The “same layer” here refers to that a film layer for forming specific patterns is formed by using a same film-forming process, and then a patterning process is performed on the film layer by using a same mask to form a layer structure. Depending on different specific patterns, the patterning process may include several exposure, development and etching processes. The specific patterns in the formed layer structure may be continuous or discontinuous, and these specific patterns may also be at different heights or have different thicknesses. Thus, the common electrode 30 and the first sub-lines (or the first sub-gates 181) may be simultaneously formed in a single patterning process, so that the manufacturing process of the array substrate 100 may be simplified.

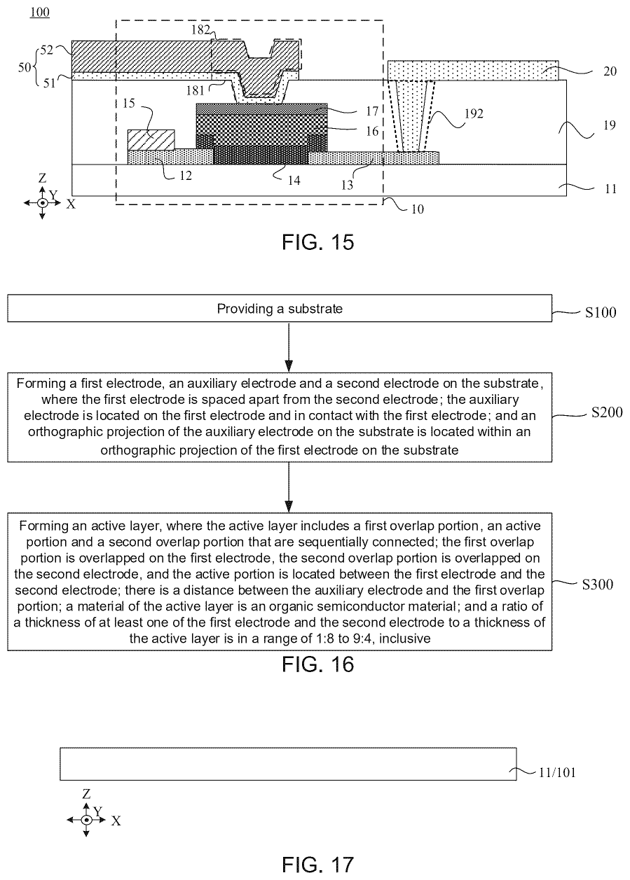

In some other embodiments, as shown in FIG. 15, the pixel electrode 20 is located on a side of the passivation layer 19 away from the substrate 11. The first sub-line 51 is disposed in the same layer as the pixel electrode 20. Since the first sub-gates 181 in the same row are electrically connected to each other to form the first sub-line 51, the first sub-gates 181 are disposed in the same layer as the pixel electrode 20. Thus, the pixel electrode 20 and the first sub-lines 51 (or the first sub-gates 181) may be simultaneously formed in a single patterning process, so that the manufacturing process of the array substrate 100 may be simplified.

It can be understood that in a case where the pixel electrode 20 is located on a side of the passivation layer 19 away from the substrate 11, the passivation layer 19 further includes a second via hole 192. The second via hole 192 exposes part of a surface of the second electrode 13 of the organic thin film transistor 10 away from the substrate 11. A portion of the pixel electrode 20 is filled in the second via hole 192 and is in contact with the second electrode 13 of the organic thin film transistor 10, so as to achieve electrical connection between the pixel electrode 20 and the second electrode 13 of the organic thin film transistor 10.

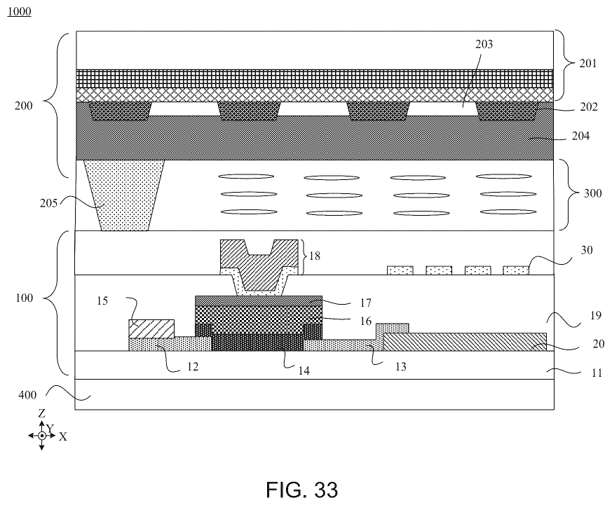

In some embodiments, as shown in FIGS. 2 and 33, the display device 1000 further includes a color film substrate 200.

The color film substrate 200 further includes a second substrate 201, a black matrix 202, color filters 203, a first protective layer 204, a post spacer 205, and the like.

It can be understood that in a process of assembling the array substrate 100 and the color film substrate 200 to form the display device 1000, the color film substrate 200 is turned upside down and then assembled. The display device 1000 may include a plurality of post spacers 205, a plurality of organic thin film transistors 10, a plurality of pixel electrodes 20, and the like. For ease of illustration, FIG. 33 only illustrates a single organic thin film transistor 10 and a single pixel electrode 20 in the display device 1000.

The second substrate 201 provides support for the color film substrate 200. The black matrix 202 is provided between two adjacent color filters 203 to separate the adjacent color filters 203, thereby avoiding affecting the display effect of the display device 1000 caused by color mixing between lights exit from the adjacent color filters 203. In addition, the display device 1000 includes a display area and a peripheral area. The black matrix 202 can also be set in a region of the display area adjacent to the peripheral area, so as to prevent oblique light in the peripheral area from exiting from the display area, thereby preventing edge light leakage in the display area of the display device 1000.

The first protective layer 204 is used to protect the color filters 203 and the like. The post spacer 205 is located on the first protective layer 204 and plays a role of supporting the array substrate 100.

The color filter 203 is used to filter light. The type of the color filter 203 varies, and may be set depending on actual conditions. For example, in a case where the backlight provided by the backlight module 400 is white light, the color filters may include red filters, green filters and blue filters. For example, the red filter may only allow red light in the incident light to pass through, the green filter may only allow green light in the incident light to pass through, and the blue filter may only allow blue light in the incident light to pass through. As another example, in a case where the backlight provided by the backlight module 400 is blue light, the color filters may include a red filter and a green filter.

For example, the liquid crystal layer 300 in the display device 100 includes a plurality of liquid crystal molecules. For example, an electric field may be created between the pixel electrode 20 and the common electrode 30 due to action of a pixel voltage and a common voltage, and liquid crystal molecules in the liquid crystal layer 300 may be deflected due to action of the electric field.

It can be understood that the backlight provided by the backlight module 400 may pass through the array substrate 100 to be incident on the liquid crystal molecules in the liquid crystal layer 300. The liquid crystal molecules are deflected due to the action of the electric field created between the pixel electrode 20 and the common electrode 30, so as to change the amount of the light passing through the liquid crystal molecules, so that the light exiting through the liquid crystal molecules reaches preset brightness. The light exits after passing through the color filters of different colors in the color film substrate 200. The exit light includes light of various colors, such as red light, green light and blue light, and the light of various colors cooperate to enable the display device 1000 to achieve display.

The structure (e.g., direct-type backlight or side-type backlight) of the backlight module 400 varies, and may be selected depending on actual needs, and may not be limited in the embodiments of the present disclosure.

It can be understood that the beneficial effects that may be achieved by the array substrate 100 and the display device 100 provided in some embodiments of the present disclosure are the same as the beneficial effects that may be achieved by the organic thin film transistor 10 provided in some of the above embodiments, and details are not repeated here.

Furthermore, some embodiments of the present disclosure provide a method for manufacturing an organic thin film transistor 10. The manufacturing method may be used to manufacturing the organic thin film transistor 10 in any of the embodiments described above. As shown in FIG. 16, the manufacturing method includes S100 to S300.

In S100, as shown in FIG. 17, a substrate 11 is provided.

For a structure of the substrate 11, reference may be made to the explanation in some embodiments described above, and details are not repeated here.

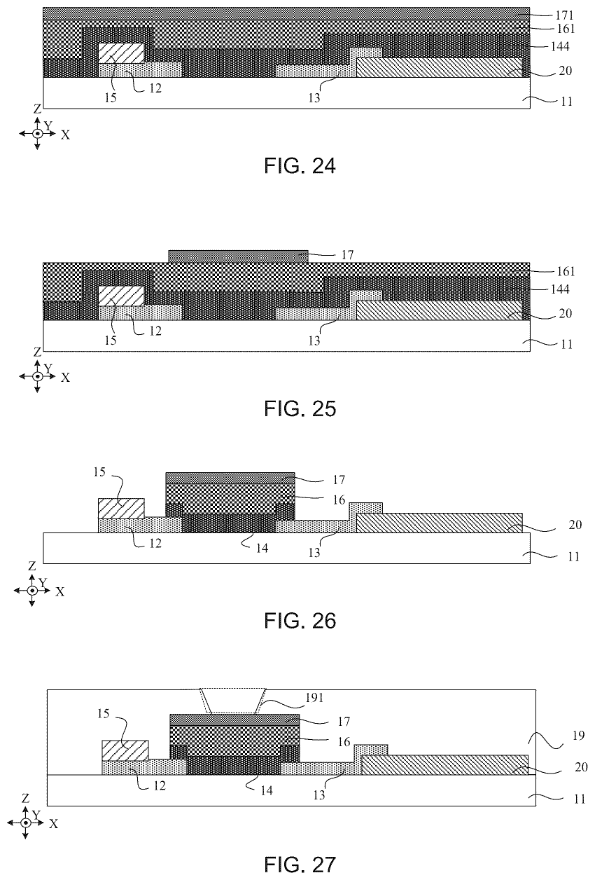

In S200, as shown in FIG. 24, a first electrode 12, an auxiliary electrode 15 and a second electrode 13 are formed on the substrate 11. The first electrode 12 is spaced apart from the second electrode 13; the auxiliary electrode 15 is located on the first electrode 12 and in contact with the first electrode 12; and an orthographic projection of the auxiliary electrode 15 on the substrate 11 is located within an orthographic projection of the first electrode 12 on the substrate 11.

For example, the first electrode 12 and the second electrode 13 may be made of the same material. The materials of the first electrode 12 and the second electrode 13 will be described below by considering the first electrode 12 as an example.

For example, the material of the first electrode 12 may be metal silver (Ag) and a self-assembled monolayer (SAM) material on a surface of the metal silver. The SAM material may be used to control electron transfer in the first electrode 12 and may also protect metal silver from being corroded by irritating chemicals and etchants, thereby facilitating improvement of the carrier mobility of the first electrode 12. The valence band of the first electrode 12 composed of silver and SAM is 5.86 eV.

As another example, the material of the first electrode 12 may be a single metal, such as gold (Au), platinum (Pt) or palladium (Pd). The valence band of gold is 5.2 eV, the valence band of platinum is 5.6 eV, and the valence band of palladium is 5.12 eV. As a result, the valence band of the first electrode 12 and the HOMO energy level or the LUMO energy level of the active layer 14 may have a small energy level difference therebetween, and the valence band of the second electrode 13 and the HOMO energy level or the LUMO energy level of the active layer 14 may have a small energy level difference therebetween, so that interfaces where the first electrode 12 and the second electrode 13 are in contact with the active layer 14 have relatively low Schottky barrier, which facilitates carrier transport from the first electrode 12 to the active layer 14 and carrier transport from the second electrode 13 to the active layer 14, thereby improving the electrical properties of the organic thin film transistor 10.

As another example, the material of the first electrode 12 may be a metal material and a corresponding metal oxide material, or a metal alloy material and a corresponding metal alloy oxide material. The molybdenum alloy here may be an alloy of molybdenum, tantalum (Ta) and niobium (Nb). The molybdenum undergoes surface oxidation treatment to obtain a surface oxide, and a valence band of the first electrode 12 composed of molybdenum and the surface oxide is 5.58 eV. The molybdenum alloy undergoes surface oxidation treatment to obtain a surface oxide of the molybdenum alloy, and a valence band of the first electrode 12 composed of the molybdenum alloy and the surface oxide is 5.5 eV. The material of the first electrode 12 may also be titanium nitride (TIN), which has a valence band in a range of 4.49 eV to 5.29 eV, inclusive. The valence band of the first electrode 12 or the second electrode 13 made of the above material and the HOMO energy level and the LUMO energy level of the active layer 14 have small differences therebetween, so as to reduce the Schottky barrier of the interface where the first electrode 12 or the second electrode 13 is in contact with the active layer 14, thereby facilitating the carrier transport from the first electrode 12 to the active layer 14 or the carrier transport from the second electrode 13 to the active layer 14.

For example, a material of the auxiliary electrode 15 may be a metal material with a relatively low resistance.

The auxiliary electrode 15 may be composed of a single film layer, and a material of the single film layer may be copper (Cu) or the like.

The auxiliary electrode 15 may be composed of a plurality of stacked film layers, and materials of the plurality of film layers may be different metals. For example, the auxiliary electrode 15 may include a titanium (Ti) metal layer, an aluminum (Al) metal layer and a titanium metal layer stacked in sequence.

For example, a thickness of the auxiliary electrode 15 is in a range of 400 nm to 600 nm, inclusive.

For example, the thickness of the auxiliary electrode 15 is 400 nm, 460 nm, 520 nm, 580 nm or 600 nm.

In this way, the resistance of the auxiliary electrode 15 may be reduced, the loss the data signal during transmission may be reduced, and the accuracy of the data signal may be improved.

In S300, as shown in FIG. 27, an active layer 14 is formed. The active layer 14 includes a first overlap portion 141, an active portion 142 and a second overlap portion 143 that are sequentially connected. The first overlap portion 141 is overlapped on the first electrode 12, the second overlap portion 143 is overlapped on the second electrode 13, and the active portion 142 is located between the first electrode 12 and the second electrode 13. There is a distance between the auxiliary electrode 15 and the first overlap portion 141. A material of the active layer 14 is an organic semiconductor material. A ratio of a thickness of at least one of the first electrode 12 and the second electrode 13 to a thickness of the active layer 14 is in a range of 1:8 to 9:4, inclusive.

For a structure of the active layer 14, reference may be made to the explanation in some embodiments described above, and details are not repeated here.

The embodiments of the present disclosure adopt the above manufacturing method to form the first electrode 12, the second electrode 13 and the auxiliary electrode 15 on the substrate 11, and form the active layer 14. The first overlap portion 141 of the active layer 14 is overlapped on the first electrode 12, and the second overlap portion 143 of the active layer 14 is overlapped on the second electrode 13. The auxiliary electrode 15 and the first overlap portion 141 have a distance therebetween, and the ratio of the thickness of the at least one of the first electrode 12 and the second electrode 13 to the thickness of the active layer 14 is in a range of 1:8 to 9:4, inclusive. In this way, the formed first electrode 12 and the substrate 11 may have a small step difference therebetween, and the formed second electrode 13 and the substrate 11 may have a small step difference therebetween. As a result, the material of the active layer may climb a relatively low height, thereby alleviating or even eliminating occurrence of cracks and fractures between the first overlap portion 141 of the active layer 14 and the active portion 142 or between the second overlap portion 143 of the active layer 14 and the active portion 142. Thus, normal transport of the carriers in the active layer 14 may be ensured, so as to guarantee electrical properties of the organic thin film transistor 10 and guarantee the accuracy of the signal transmitted by the organic thin film transistor 10. In addition, the formed auxiliary electrode 15 covers a portion of the first electrode 12 and there is a distance between the auxiliary electrode 15 and the first overlap portion 141. Thus, the auxiliary electrode 15 may be used to reduce an overall resistance of the first electrode 12 and the auxiliary electrode 15, so that a signal (e.g., data signal) has a small loss on the first electrode 12 and the auxiliary electrode 15, which is beneficial to ensuring an accuracy of the signal transmitted by the organic thin film transistor 10, thereby further ensuring a good display effect of the display device 1000.

In some embodiments, forming the first electrode 12, the auxiliary electrode 15 and the second electrode 13 on the substrate 11 in S200 includes S210 to S250.

In S210, as shown in FIG. 19, a first conductive film 121 and a second conductive film 151 are formed sequentially on the substrate 11.

For example, a material of the first conductive film 121 may refer to the material of the first electrode 12 described above, and a material of the second conductive film 151 may refer to the material of the auxiliary electrode 15 described above.

For example, the first conductive film 121 and the second conductive film 151 may be formed using the same manufacturing process.

Considering a manufacturing process of the first conductive film 121 as an example, the first conductive film 121 may be formed by electron beam evaporation, thermal evaporation or sputtering.

For example, a thickness of the first conductive film 121 may be in a range of 10 nm to 90 nm, inclusive, and a thickness of the second conductive film 151 may be in a range of 400 nm to 600 nm, inclusive.

The thickness of the first conductive film 121 may be 10 nm, 20 nm, 40 nm, 70 nm or 90 nm.

The thickness of the second conductive film 151 may be 400 nm, 450 nm, 510 nm, 570 nm or 600 nm.

In S220, as shown in FIG. 20, a photoresist film 122 is formed on the second conductive film 151.

For example, the photoresist film 122 may be formed by spin coating. The photoresist film 122 covers a whole layer of second conductive film 151.

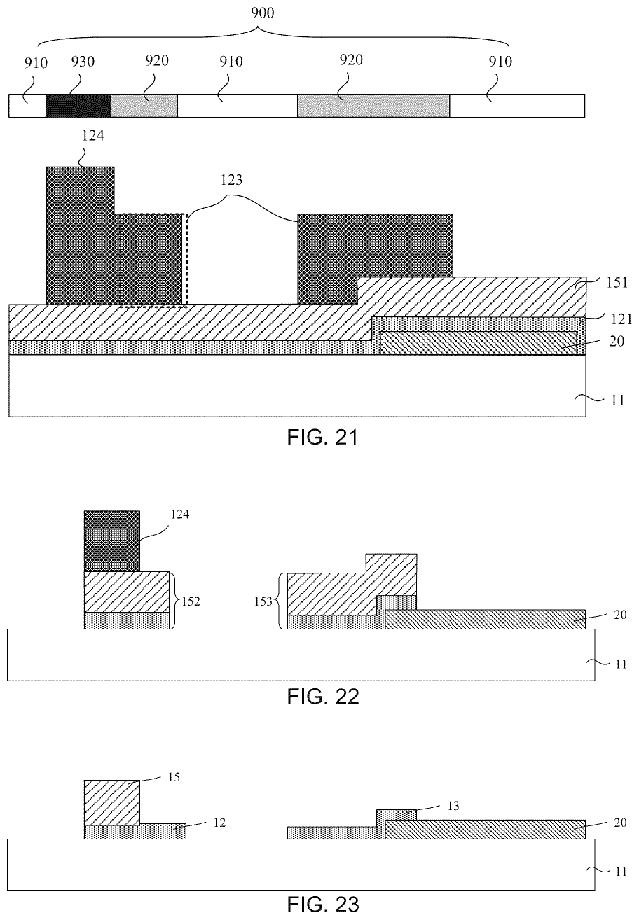

In S230, as shown in FIG. 21, the photoresist film 122 is exposed and developed using a halftone mask 900. The halftone mask 900 has completely transparent areas 910, first semi-transparent areas 920 and an opaque area 930. Portions of the photoresist film 122 located in the completely transparent areas 910 are removed; portions of the photoresist film 122 located in the first semi-transparent areas 920 are thinned to obtain first photoresist patterns 123; and a portion of the photoresist film 122 located in the opaque area 930 is retained to obtain a second photoresist pattern 124.

For example, a thickness of the first photoresist pattern 123 is less than a thickness of the second photoresist pattern 124.

In S240, as shown in FIG. 22, with the first photoresist patterns 123 and the second photoresist pattern 124 as the mask, the first conductive film 121 and the second conductive film 151 are etched to remove the first photoresist patterns 123 and thin the second photoresist pattern 124 simultaneously, so as to obtain a first conductive pattern 152 and a second conductive pattern 153.

In a case where the second conductive film 151 includes a titanium (Ti) metal layer, an aluminum (Al) metal layer and a titanium (Ti) metal layer that are stacked in sequence, in the above description of “the first conductive film and the second conductive film are etched”, the second conductive film 151 may be etched by dry etching, and then the first conductive film 121 may be etched by wet etching.

In a case where the material of the second conductive film 151 is copper, in the above description of “the first conductive film and the second conductive film are etched”, the second conductive film 151 and the first conductive film 121 may both be etched by wet etching. Of course, different etchants are selected for wet etching of the second conductive film 151 and the first conductive film 121. In a case where the second conductive film 151 is etched with the etchant, the etchant will not etch the first conductive film 121.

In S250, as shown in FIGS. 22 and 23, with the thinned second photoresist pattern 124 as a mask, portions of the first conductive pattern 152 and the second conductive pattern 153 located in the second conductive film 151 are etched to retain portions of the first conductive pattern 152 and the second conductive pattern 153 located in the first conductive film 121, so as to obtain the first electrode 12 and the second electrode 13, and to retain a portion of the first conductive pattern 152 and the second conductive pattern 153 located in the second conductive film 151 and covered by the thinned second photoresist pattern 124, so as to obtain the auxiliary electrode 15.

In a case where the second conductive film 151 includes a titanium (Ti) metal layer, an aluminum (Al) metal layer and a titanium (Ti) metal layer that are stacked in sequence, the portions of the first conductive pattern 152 and the second conductive pattern 153 located in the second conductive film 151 are etched by dry etching in S250. In a case where the material of the second conductive film 151 is Cu, the portions of the first conductive pattern 152 and the second conductive pattern 153 located in the second conductive film 151 are etched by wet etching in S250.

With the above manufacturing method, the first electrode 12, the second electrode 13 and the auxiliary electrode 15 may be formed simultaneously, thereby simplifying the manufacturing process of the organic thin film transistor 10.

In some embodiments, forming the active layer 14 in S300 in the above manufacturing method includes S310 to S330.

In S310, as shown in FIG. 24, an active film 144, a gate insulating film 161 and an auxiliary film 171 are sequentially formed on the substrate 11, the first electrode 12, the auxiliary electrode 15 and the second electrode 13.

For example, a material of the gate insulating film 161 is an organic material.

For example, the material of the gate insulating film 161 may be an organic material with low polarity, such as CYTOP (perfluoro(1-butenyl vinyl ether) polymer, amorphous fluorinated polymer fluororesin), PMMA (polymethyl methacrylate), PVP (polyvinyl pyrrolidone) and other organic polymer materials. Therefore, the formed gate insulating layer 16 may ensure the high carrier mobility, so as to avoid reducing the carrier mobility due to formation of dipoles on a surface of the gate insulating layer 16 by the carriers, which help improve the electrical properties of the organic thin film transistor 10.

For example, a thickness of the gate insulating film 161 is about 300 nm.

For example, the active film 144 and the gate insulating film 161 may be formed using the same process. Considering a formation process of the active thin film 144 as an example, the active thin film 144 may be formed by spin coating or slot die coating.

It can be understood that since the material of the auxiliary layer 17 may be an organic material or a conductive material, the material of the auxiliary film 171 may also be an organic material or a conductive material. The auxiliary films 171 made of different materials may be formed by different processes.

For example, in a case where the material of the auxiliary film 171 is an organic material, the auxiliary film 171 may be formed by spin coating or slot die coating. As another example, in a case where the material of the auxiliary film 171 is a conductive material such as ITO (indium tin oxide), the auxiliary film 171 may be formed by sputtering or evaporation.

In S320, as shown in FIG. 25, the auxiliary film 171 is patterned to form an auxiliary layer 17.

For example, the auxiliary film 171 may be processed by wet etching to obtain the auxiliary layer 17.

In S330, as shown in FIG. 26, the gate insulating film 161 and the active film 144 are patterned with the auxiliary layer 17 as a mask to form a gate insulating layer 16 and the active layer 14.

For example, the gate insulating film 161 and the active film 144 may be patterned by dry etching.

With the above method, the gate insulating layer 16 and the active layer 14 may be formed simultaneously in a single process, thereby simplifying the manufacturing process of the organic thin film transistor 10. Moreover, direct etching of the active layer 14 may be avoided, so as to avoid affecting the stability of the active layer 14, thereby ensuring the normal operation of the active layer 14 in the organic thin film transistor 10.

In some embodiments, after forming the gate insulating layer 16 and the active layer 14 in S330, the manufacturing method further includes S340 to S360.

In S340, as shown in FIG. 27, a passivation layer 19 is formed on the auxiliary layer 17. The passivation layer 19 includes a first via hole 191.

For example, a passivation film may be formed by spin coating or slit coating, and then the passivation film is patterned to form the first via hole 191, so as to obtain the passivation layer 19. For example, the passivation layer 19 further covers the auxiliary electrode 15, the first electrode 12 and the second electrode 13.

The first via hole 191 exposes part of a surface of the auxiliary layer 17 away from the substrate 11.

For example, a material of the passivation layer 19 includes an organic polymer material, such as a fluorine-containing polymer material doped with a photosensitizer. Since the material of the passivation layer 19 has photosensitivity, the passivation film may be patterned by photolithography, thereby reducing the manufacturing cost of the passivation layer 19 and the organic thin film transistor 10 and avoiding a high manufacturing cost caused by the use of etching and other processes. Furthermore, the material of the passivation layer 19 contains fluorine, so that the formed passivation layer 19 has certain hydrophobicity, thereby improving moisture and oxygen resistance of the passivation layer 19 and enhancing the protective capability of the passivation layer 19 for the organic thin film transistor 10.

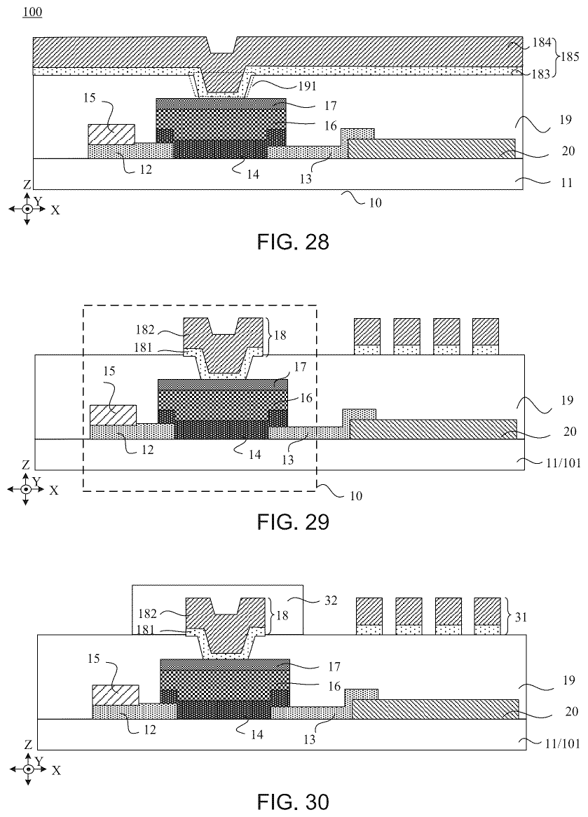

In S350, as shown in FIG. 28, a gate film 185 is formed on the passivation layer 19.

For example, a material of the gate film 185 includes a conductive material.

In a case where the gate 18 includes the first sub-gate 181 and the second sub-gate 182, the gate film 185 may include a third conductive film 183 and a fourth conductive film 184 that are stacked. The third conductive film 183 is in contact with the passivation layer 19. A material of the third conductive film 183 and a material of the fourth conductive film 184 may be the same or different.

For example, the material of the third conductive film 183 is ITO or the like. A thickness of the third conductive film 183 may be in a range of 70 nm to 100 nm, inclusive. The thickness of the third conductive film 183 is 70 nm, 80 nm, 85 nm, 92 nm or 100 nm.

A material of the fourth conductive film 184 may be a material with a relatively low resistance. The fourth conductive film 184 may be formed by stacking a plurality of film layers in sequence. For example, the plurality of film layers may be a buffer film/a low resistance film/a buffer film. Here, a material of the buffer film may be molybdenum, molybdenum alloy, titanium or the like. A material of the low resistance film may be copper, aluminum, silver or the like. A thickness of the fourth conductive film 184 may be in a range of 400 nm to 800 nm, inclusive. The thickness of the fourth conductive film 184 may be 400 nm, 480 nm, 670 nm, 720 nm or 800 nm.

In S360, as shown in FIG. 29, the gate film 185 is patterned to form a gate 18. The gate 18 is in contact with the auxiliary layer 17 through the first via hole 191.

For example, the gate film 185 may be patterned by dry etching or wet etching.

For example, the fourth conductive film 184 is patterned to obtain a second sub-gate 182, and the third conductive film 183 is patterned to obtain a first sub-gate 181. The first sub-gate 181 and the second sub-gate 182 constitute the gate 18.

Furthermore, some embodiments of the present disclosure provide a method for manufacturing an array substrate 100. The manufacturing method may be used for manufacturing the array substrate 100 described in some of the above embodiments.

The method for manufacturing the array substrate 100 will be described below by considering an example where the array substrate 100 includes a plurality of organic thin film transistors 10 with top-gate bottom-contact structures. Specifically, the manufacturing method includes S710 to S740.

In S710, as shown in FIG. 17, a first substrate 101 is provided.

It can be understood that the manufacturing process of the array substrate 100 includes formation of a plurality of organic thin film transistors 10. Therefore, the first substrate 101 in the array substrate 100 may also be used as the substrate 11 in the organic thin film transistors 10.

For example, a material of the first substrate 101 may be the same as or different from the material of the substrate 11 in the above embodiments.

For example, the first substrate 101 may include a plurality of stacked sub-layers, and the plurality of sub-layers may be a rigid substrate, a soft film layer and a planarization layer in sequence.

The rigid substrate may be made of a glass material, and is used to provide support for the manufacture of the array substrate 100. A material of the soft film layer may be TAC (triacetyl cellulose) or the like. The TAC has a low light delay characteristic, so that the backlight provided by the backlight module 400 does not substantially undergo a phase change when passing through the array substrate 100. A material of the planarization layer may be a resin material, such as UV-cured epoxy resin, PI or photosensitive resin SU-8. A surface of the planarization layer away from the rigid substrate is a flat surface, thereby providing a good interface environment for the pixel electrodes, the organic thin film transistors and the like that will be formed subsequently.

In addition, in order to facilitate peeling of the rigid substrate in the first substrate 101 during forming the display device 1000 with the array substrate 100 and the color film substrate 200, an adhesive layer is further included between the soft film layer and the rigid substrate in the first substrate 101. A material of the adhesive layer may include thermal debonding adhesive, PET (polyethylene terephthalate) debonding adhesive, UV (ultra violet) debonding adhesive, or the like.

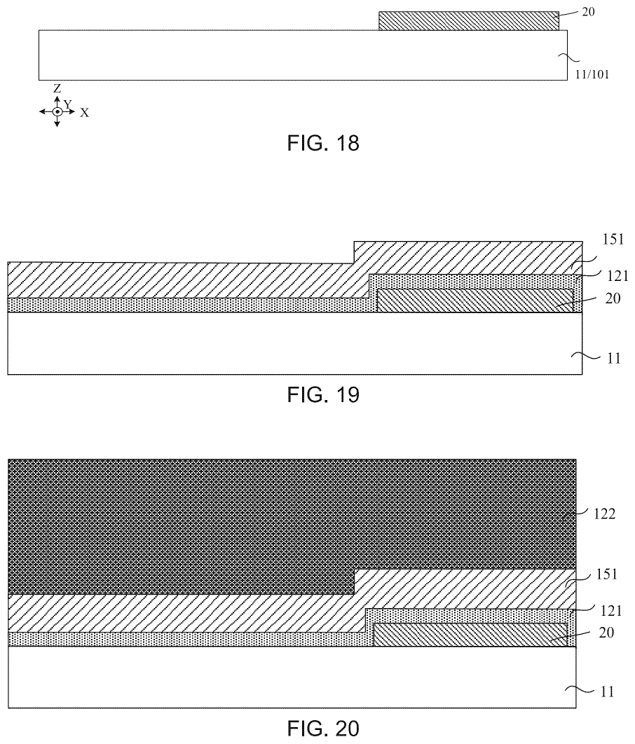

In S720, as shown in FIG. 18, a pixel electrode 20 is formed on the first substrate 101.

For example, a whole layer of pixel thin film may be formed by sputtering, and then the pixel thin film may be patterned by etching to obtain the pixel electrode 20.

In S730, as shown in FIG. 29, an organic thin film transistor 10 is formed on the first substrate 101.

The above S730 may refer to the method for manufacturing the organic thin film transistor 10 provided in the above embodiments, and details are not repeated here.

It can be understood that as shown in FIG. 23, during forming the second electrode 13 of the organic thin film transistor 10, a portion of the second electrode 13 is overlapped on the pixel electrode 20.

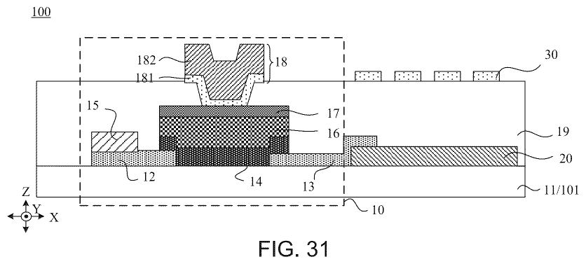

In S740, as shown in FIG. 31, a common electrode 30 is formed on the passivation layer 19 of the organic thin film transistor 10.

It can be understood that in S350 in the method for manufacturing the organic thin film transistor 10 provided in the above embodiments, the gate film 185 is patterned to form the gate 18, and to form the common film 31 (as shown in FIG. 30) at the same time. Then, a third photoresist pattern 32 is formed using a mask. The third photoresist pattern 32 covers the gate 18. With the third photoresist pattern 32 as a mask, portions of the common film 31 located in the fourth conductive film 184 are etched, and portions of the common film 31 located in the third conductive film 183 are retained, so as to obtain the common electrode 30. Therefore, the common electrode 30 may be formed simultaneously in the process of forming the gate 18, so as to avoid forming the common electrode 30 separately, thereby simplifying the manufacturing processes of the common electrode 30 and the array substrate 100.

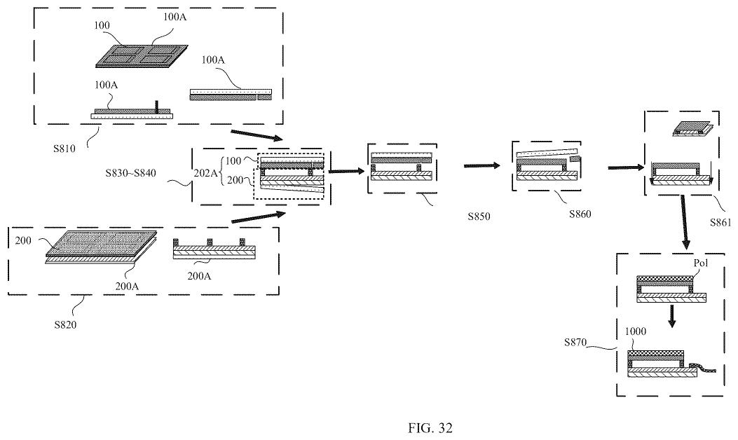

Furthermore, some embodiments of the present disclosure provide a method for manufacturing a display device 1000. The display device 1000 may achieve flexible display. The display device 1000 includes the organic thin film transistor 10 described in any of the above embodiments or the array substrate 100 described in any of the above embodiments. As shown in FIG. 32, the manufacturing method includes S810 to S870.

In S810, as shown in FIG. 32, an array substrate motherboard 100A is provided. The array substrate motherboard 100A includes a plurality of array substrates 100 arranged at intervals.

For example, the plurality of array substrates 100 are arranged in an array.

In S820, as shown in FIG. 32, a color film substrate motherboard 200A is provided. The color film substrate motherboard 200A includes a plurality of color film substrates 200 arranged at intervals.

For example, the plurality of color film substrates 200 are arranged in an array.

For example, the color film substrate 200 includes a second substrate, a black matrix layer, a filter layer, a protective layer and a post spacer that are stacked in sequence.

For example, a structure of the second substrate may refer to the structure of the first substrate 101 in the array substrate 100, and details are not repeated here.

In S830, as shown in FIG. 32, the array substrate motherboard 100A and the color film substrate motherboard 200A are assembled together to form a first display intermediate body.

For example, before assembly, a liquid crystal alignment layer needs to be formed. For example, the liquid crystal alignment layer is made of PI, and PI is processed using a rubbing process to obtain the liquid crystal alignment layer.

For example, before assembly, the array substrate motherboard 100A may be turned upside down and then assembled with the color film substrate motherboard 200A.

For example, during assembly, a liquid crystal filling process is performed on the space corresponding to the array substrate 100 and the color film substrate 200 to form a liquid crystal layer.

In S840, the first display intermediate body is cut to obtain a plurality of second display intermediate bodies 202A. Each second display intermediate body 202A includes an array substrate and a corresponding color film substrate.

For example, the first display intermediate body may be cut by laser.

It can be understood that each color film substrate 200 in the color film substrate motherboard 200A may be cut to obtain a single color film substrate 200, and each array substrate in the array substrate motherboard 100A may be cut to obtain a single array substrate 100, then the single color film substrate 200 may be assembled with the single array substrate 100.

In S850, as shown in FIG. 32, the array substrate in the second display intermediate body is heated to peel off the rigid substrate in the array substrate.

For example, the thermal debonding adhesive in the adhesive layer of the first substrate of the array substrate may be separated from the rigid substrate during heating, so that the rigid substrate may be peeled off.

For example, the rigid substrate of the first substrate is removed, and the flexible soft film layer and the flexible planarization layer in the first substrate are retained, thereby facilitating realization of flexible display of the display device.

In S860, as shown in FIG. 32, the color film substrate in the second display intermediate body is UV-irradiated to peel off a rigid substrate in the color film substrate.

For example, the UV debonding adhesive in the adhesive layer of the second substrate of the color film substrate may be separated from the rigid substrate during UV irradiation, so that the rigid substrate may be peeled off.

For example, the rigid substrate of the second substrate in the color film substrate is removed, and the flexible soft film layer and the flexible planarization layer in the second substrate are retained, thereby facilitating realization of flexible display of the display device.

In S870, as shown in FIG. 32, a polarizer Pol is formed on the color film substrate of the second display intermediate body, and the array substrate is bonded to a driver chip to form the display device 1000.

For example, data lines in the array substrate may receive data signals provided by the driver chip.

For example, before attaching the polarizer Pol, the above manufacturing method further includes S861 in which an edge of the second display intermediate body is cut.

For example, after the array substrate is bonded to the driver chip, the method for manufacturing the display device 1000 further includes: forming a backlight module 400 on a side of the array substrate 100 away from the color film substrate 200.

FIG. 33 is a structural diagram of the display device 1000 formed by the above manufacturing method.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. An organic thin film transistor, comprising:
a substrate; and
a first electrode and a second electrode located on the substrate; the first electrode and the second electrode being spaced apart;
an active layer including a first overlap portion, an active portion and a second overlap portion that are connected in sequence, wherein the first overlap portion is overlapped on the first electrode, the second overlap portion is overlapped on the second electrode, and the active portion is located between the first electrode and the second electrode; and
an auxiliary electrode located on the first electrode and in contact with the first electrode, wherein an orthographic projection of the auxiliary electrode on the substrate is located within an orthographic projection of the first electrode on the substrate; and the auxiliary electrode and the first overlap portion have a distance therebetween, wherein
a material of the active layer is an organic semiconductor material, and a ratio of a thickness of at least one of the first electrode and the second electrode to a thickness of the active layer is in a range of 1:8 to 9:4, inclusive.

2. The organic thin film transistor according to claim 1, wherein a thickness of the auxiliary electrode is greater than a thickness of the first electrode.

3. The organic thin film transistor according to claim 1, wherein a ratio of a thickness of the auxiliary electrode to the thickness of the active layer is in a range of 5:1 to 15:1, inclusive.

4. The organic thin film transistor according to claim 1, further comprising:
a gate insulating layer located on the active layer, wherein a material of the gate insulating layer including an organic material;
an auxiliary layer located on the gate insulating layer, wherein orthographic projections of the auxiliary layer, the gate insulating layer and the active layer on the substrate coincide; and
a gate located on the auxiliary layer and in contact with the auxiliary layer.

5. The organic thin film transistor according to claim 4, wherein a material of the auxiliary layer includes a conductive material or an organic material.

6. The organic thin film transistor according to claim 4, further comprising a passivation layer, wherein
the passivation layer is located on a side of the auxiliary layer away from the substrate; the passivation layer includes a first via hole; and a material of the passivation layer includes an organic material; and
the gate is located on the passivation layer; the gate includes a first sub-gate and a second sub-gate that are stacked; and the first sub-gate is in contact with the auxiliary layer through the first via hole.

7. The organic thin film transistor according to claim 1, further comprising:
a gate located on a side of the active layer proximate to the substrate; and
a protective layer located on a surface of the active layer away from the substrate, wherein an orthographic projection of the protective layer on the substrate coincides with an orthographic projection of the active layer on the substrate, and a material of the protective layer includes an organic material.

8. The organic thin film transistor according to claim 7, further comprising a gate insulating layer, wherein
the gate insulating layer is located between the active layer and the gate; and a material of the gate insulating layer includes an organic material.

9. The organic thin film transistor according to claim 1, wherein the material of the active layer includes polythiophene-based semiconductor materials and pentacene-based small molecule semiconductor materials; and/or the substrate includes a flexible substrate.

10. The organic thin film transistor according to claim 1, wherein the thickness of the at least one of the first electrode and the second electrode is in a range of 10 nm to 90 nm, inclusive; and/or
the thickness of the active layer is in a range of 40 nm to 80 nm, inclusive.

11.-12. (canceled)

13. A method for manufacturing an organic thin film transistor, comprising:
providing a substrate;
forming a first electrode, an auxiliary electrode and a second electrode on the substrate, wherein the first electrode and the second electrode are spaced apart; the auxiliary electrode is located on the first electrode and in contact with the first electrode; and an orthographic projection of the auxiliary electrode on the substrate is located within an orthographic projection of the first electrode on the substrate; and
forming an active layer, wherein the active layer includes a first overlap portion, an active portion and a second overlap portion that are connected in sequence; the first overlap portion is overlapped on the first electrode, the second overlap portion is overlapped on the second electrode, and the active portion is located between the first electrode and the second electrode; the auxiliary electrode and the first overlap portion have a distance therebetween; a material of the active layer is an organic semiconductor material, and a ratio of a thickness of at least one of the first electrode and the second electrode to a thickness of the active layer is in a range of 1:8 to 9:4, inclusive.

14. The method according to claim 13, wherein forming the first electrode, the auxiliary electrode and the second electrode on the substrate includes:
forming a first conductive film and a second conductive film sequentially on the substrate;
forming a photoresist film on the second conductive film;
performing exposure and development on the photoresist film using a halftone mask, wherein the halftone mask has a completely transparent area, a first semi-transparent area and an opaque area; a portion of the photoresist film located in the completely transparent area is removed; a portion of the photoresist film located in the first semi-transparent area is thinned to obtain a first photoresist pattern; and a portion of the photoresist film located in the opaque area is retained to obtain a second photoresist pattern;
with the first photoresist pattern and the second photoresist pattern as a mask, etching the first conductive film and the second conductive film to remove the first photoresist pattern and thin the second photoresist pattern simultaneously to obtain a first conductive pattern and a second conductive pattern; and
with the thinned second photoresist pattern as a mask, etching portions of the first conductive pattern and the second conductive pattern located in the second conductive film, to retain portions of the first conductive pattern and the second conductive pattern located in the first conductive film to obtain the first electrode and the second electrode, and to retain a portion of the first conductive pattern and the second conductive pattern located in the second conductive film and covered by the thinned second photoresist pattern to obtain the auxiliary electrode.

15. The method according to claim 13 [[or 14]], wherein forming the active layer includes:
forming an active film, a gate insulating film and an auxiliary film sequentially on the substrate, the first electrode, the auxiliary electrode and the second electrode;
performing patterning on the auxiliary film to form an auxiliary layer; and
performing patterning on the gate insulating film and the active film with the auxiliary layer as a mask to form a gate insulating layer and the active layer.

16. The method according to claim 15, wherein after forming the gate insulating layer and the active layer, the method further comprises:
forming a passivation layer on the auxiliary layer, wherein the passivation layer includes a first via hole;
forming a gate film on the passivation layer; and
performing patterning on the gate film to form a gate, wherein the gate is in contact with the auxiliary layer.

17. An array substrate, comprising:
a plurality of organic thin film transistors each according to claim 1; and
a plurality of pixel electrodes electrically connected to second electrodes of the plurality of organic thin film transistors, respectively.

18. The array substrate according to claim 17, further comprising data lines, wherein
the plurality of organic thin film transistors are arranged in an array; first electrodes of organic thin film transistors located in a same column are electrically connected to each other, and auxiliary electrodes of the organic thin film transistors located in the same column are electrically connected to each other, so as to form a data line.

19. The array substrate according to claim 17, wherein each pixel electrode is located between a second electrode of a corresponding organic thin film transistor and the substrate, and a portion of the second electrode of the organic thin film transistor is overlapped on the pixel electrode.

20. The array substrate according to claim 19, further comprising a common electrode and gate lines, wherein
the organic thin film transistors each further include a passivation layer and a gate located on a side of the passivation layer away from the substrate; the gate includes a first sub-gate and a second sub-gate that are stacked, and the common electrode is located on a side of the passivation layer in the organic thin film transistor away from the substrate;
the plurality of organic thin film transistors are arranged in an array; first sub-gates of gates of organic thin film transistors located in a same row are electrically connected to each other to form a first sub-line, second sub-gates of the gates of the organic thin film transistors located in the same row are electrically connected to each other to form a second sub-line; and the first sub-line and the second sub-line constitute a gate line; and
the first sub-line is disposed in a same layer as the common electrode.

21. The array substrate according to claim 17, further comprising gate lines, wherein
the organic thin film transistors each further include a passivation layer and a gate located on a side of the passivation layer away from the substrate; the gate includes a first sub-gate and a second sub-gate that are stacked;
the plurality of organic thin film transistors are arranged in an array; first sub-gates of gates of organic thin film transistors located in a same row are electrically connected to each other to form a first sub-line, second sub-gates of the gates of the organic thin film transistors located in the same row are electrically connected to each other to form a second sub-line; and the first sub-line and the second sub-line constitute a gate line;
the pixel electrodes are located on a side of the passivation layer away from the substrate; and
the first sub-line is disposed in a same layer as the pixel electrodes.

22. A display device, comprising:
the array substrate according to claim 17;
a color film substrate located on a side of the array substrate; and
a liquid crystal layer located between the array substrate and the color film substrate.
